(19) United States
(12) Patent Application Publication
(10) Pub. No.: US 2007/0012249 A1
(43) Pub. Date: Jan. 18, 2007

(54) FILM FORMING APPARATUS

(75) Inventor: Takashi MIYAZAWA, Suwa-shi, Nagano-ken (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/456,794

(22) Filed: Jul. 11, 2006

(30) Foreign Application Priority Data
Jul. 12, 2005 (JP) 2005-202494
Jul. 10, 2006 (JP) 2006-189685

(51) Int. Cl. C23C 16/00

(52) U.S. Cl. 118/723 R; 118/715

(57) ABSTRACT

A film forming apparatus includes a material reservoir that retains a material, at least one nozzle that discharges the material or a chemical species generated from the material as a precursor, and a chemical species generation section that generates the chemical species.

### BACKGROUND

1. Technical Field

The present invention relates to a film forming apparatus suitable for selective film formation and patterning using a chemical species such as a reactive species or the like.

2. Related Art

As to a method for manufacturing electronic devices such as a transistor and the like, apparatuses that form their components by a CVD process, an inkjet process, mask patterning, or the like are known. However, in an apparatus that employs a known CVD process, for example, there is a need to carry out patterning after films are formed by the CVD process. Meanwhile, in an apparatus that employs the inkjet process, nozzles need be provided with a piezoelectric element, resulting in the necessity to provide a large nozzle pitch, making fine patterning difficult. An apparatus that employs common mask patterning involves a problem of deflection of a mask, and therefore, such an apparatus sometimes cannot be used for a large-sized substrate. In addition, since the thickness of films changes with distance from an evaporation source, there is also a problem in uniformity in the thickness of the films.

WO2003/026359 discloses a film formation apparatus including: a vacuum chamber capable of being adjusted at a predetermined degree of vacuum; a nozzle connected to a material supply source while being attached to the vacuum chamber so as to supply a material from the material supply source into the vacuum chamber; a substrate stage arranged in the vacuum chamber so as to hold and fix a substrate; and a movement mechanism for moving at least one of the nozzle and the substrate stage. The relative positions of the nozzle and the substrate stage can be controlled by the movement mechanism.

WO2003/026359 is an example of related art.

### SUMMARY

The invention has been devised primarily in view of the above problems.

According to one aspect of the invention, a film forming apparatus includes a material reservoir that retains a material, at least one nozzle that discharges the material or a chemical species generated from the material as a precursor, and a chemical species generation section that generates the chemical species.

Examples of the chemical species generated by the chemical species generation section in the film forming apparatus include a reactive species, such as a radical, an ion radical, an ion, and a low-valent chemical species (e.g., carbene, silylene, germylene, etc.).

It is preferable that, in the above-described film forming apparatus, the at least one nozzle be a plurality of nozzles.

In this case, use of the plurality of nozzles makes it possible to form a plurality of films at the same time. It is also possible that the plurality of nozzles discharge a plurality of different materials at the same time. For example, in the case where at least two nozzles out of the plurality of nozzles discharge two different materials, a sort of co-deposition is possible by adjusting relative positions of the at least two nozzles so that the at least two nozzles are positioned close to each other or that gaseous materials discharged from the at least two nozzles will mix with each other in midair or on a substrate on which a film is formed.

Also, by forming a plurality of films by discharging the same chemical species with at least two nozzles out of the plurality of nozzles, it is possible to form the plurality of films so as to each have a uniform thickness and quality as variations in orifice diameter, amount of discharge, etc., between the nozzles are thus equalized.

In the above-described film forming apparatus, the chemical species generation section may be provided with a heating section. In this case, by carrying out heating at the chemical species generation section using the heating section, it is possible to evaporate the material used for film formation or cause the precursor of the material to react.

In the above-described film forming apparatus, the chemical species generation section may be configured to introduce light or provided with an optical window. In this case, by performing light irradiation at the chemical species generation section via the optical window or the like, it is possible to evaporate the material or cause the precursor of the material to react.

In the above-described film forming apparatus, the chemical species generation section may be configured to be capable of emitting an electromagnetic wave. In this case, by performing electromagnetic wave irradiation at the chemical species generation section, it is possible to evaporate the material or cause the precursor of the material to react.

The above-described film forming apparatus may further include a stage on which a substrate on which a film formed of the chemical species is to be arranged is placed.

It is preferable that the above-described film forming apparatus further include a mechanism that changes a relative position between the at least one nozzle and the stage or the substrate.

In the above-described film forming apparatus, the at least one nozzle may be capable of carrying out discharge in their respective positions that result from setting a plurality of relative positions between the at least one nozzle and the stage. In this case, it is possible to fix the distance between the nozzle and an area where a film is formed. Therefore, it is possible to reduce unevenness in thickness between portions of a film or set the thickness of each of a plurality of films at a predetermined value.

The above-described film forming apparatus may be configured to be capable of forming a plurality of films on the substrate.

In the above-described film forming apparatus, the chemical species generation section may generate a reactive species as the chemical species.

In the above-described film forming apparatus, the chemical species generation section may generate a species capable of polymerization as the chemical species.

In the above-described film forming apparatus, the material may be a compound containing metal.

The above-described film forming apparatus may further include a chamber that has arranged therein at least one nozzle and a substrate on which a film formed of the chemical species is to be arranged, and a pressure within the chamber may be adjustable so as to be 1.33322×10⁻¹ Pa or less. In this case, if the chemical species is discharged into a high vacuum atmosphere, molecules and atoms in the chemical species are cooled by adiabatic expansion. Therefore, side reaction that may occur when reacting with another chemical species is inhibited, and it is possible to induce a specific reaction. Moreover, since the molecules and atoms are inclined to become in the most stable state when being adhered to the substrate or the like, it is easy to control the molecular structure of a film formed, for example.

It is preferable that, in the above-described film forming apparatus, the at least one nozzle generate a free jet as a gaseous material.

In this case, since the molecules and atoms in the chemical species that have been turned into a free jet are generally in a cooled state, side reaction that may occur when reacting with another chemical species is inhibited, and it is possible to induce a specific reaction. Moreover, since the molecules and atoms are inclined to become in the most stable state when being adhered to the substrate or the like, it is easy to control the molecular structure of a film formed, for example.

### BRIEF DESCRIPTION OF THE DRAWINGS

The invention will now be described with reference to the accompanying drawings, wherein like numbers reference like elements.

FIG. 1 is a schematic diagram illustrating a structure of a first embodiment of a film forming apparatus according to the invention.

FIG. 2 is a schematic diagram illustrating a structure of a second embodiment of the film forming apparatus according to the invention.

FIG. 3 is a schematic diagram illustrating a structure of a third embodiment of the film forming apparatus according to the invention.

FIG. 4 is a schematic diagram illustrating an exemplary case where the first embodiment of the film forming apparatus is implemented for film formation (where a material used is ZnEt₂).

FIG. 5 shows structural formulas of exemplary materials (chemical species precursors) used in the film forming apparatus according to the invention.

FIGS. 6A to 6D are schematic process diagrams illustrating processes in direct patterning of silicon for inserting silylene using the film forming apparatus according to the invention.

FIGS. 7A to 7C are schematic process diagrams illustrating processes for manufacturing a TFT after films are formed according to the invention.

### DESCRIPTION OF EXEMPLARY EMBODIMENTS

Hereinafter, a film forming apparatus according to the invention will be described based on preferred embodiments thereof with reference to the accompanying drawings.

### First Embodiment

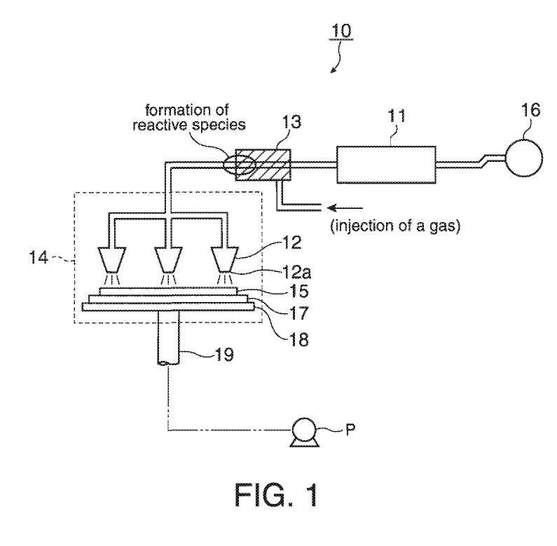

FIG. 1 is a schematic diagram illustrating a structure of a first embodiment of the film forming apparatus according to the invention.

In FIG. 1, a film forming apparatus 10 according to the first embodiment includes a material reservoir 11 for retaining a material and a plurality of nozzles 12, provided downstream of the material reservoir 11 via a flow channel, for carrying out a discharge to form a film. In addition, between the material reservoir 11 and the plurality of nozzles 12 is provided a heating section 13 that functions as a chemical species generation section for generating a chemical species, such as a reactive species or the like, with the aforementioned material as a precursor.

In addition, the film forming apparatus 10 further includes a chamber 14 that is configured to have arranged therein the plurality of nozzles 12, a substrate 15, on which a film is to be formed of the chemical species discharged from the nozzles 12, and a substrate stage 17 on which the substrate 15 is placed. The chamber 14 is connected to a vacuum device P via a pipe 19, and has a door (not shown) attached thereto in an airtight manner. The door is used to place the substrate stage 17 in an internal space of the chamber 14 and put the substrate 15 to be subjected to patterning in and out of the chamber 14.

Each nozzle 12 has a tip end at which a nozzle orifice 12a is formed, and the tip end is arranged inside the chamber 14. On the outside of the chamber 14, a rear end of the nozzle 12 is connected via the heating section 13 to the material reservoir 11, which functions as a supply source of the material. In addition, a carrier gas supply source 16 is connected to the material reservoir 11. The nozzle 12 is capable of discharging a gaseous material. In the case where the difference in pressure between the nozzle 12 and the chamber 14 is sufficiently large, the gaseous material discharged from the nozzle 12 will be in a state called a free jet or supersonic molecular jet or in a state resembling such a state. In the state called a free jet or supersonic molecular jet, the energy level, in terms of electrons, vibration, rotation, etc., of the chemical species or reactive species contained in the gaseous material discharged from the nozzle 12 is the lowest level, i.e., a so-called cooled state. Therefore, it is possible to inhibit generation of heat that may locally occur when the chemical species or reactive species reaches the substrate. This reduces influence that may be exerted on an area around a location where the film is formed, making it easy to form a fine film or pattern.

Moreover, since the chemical species or reactive species is brought into the aforementioned “cooled state”, side reaction caused by the chemical species or reactive species is inhibited. Thus, it is also possible to make uniform the structure and characteristics of the film formed of the chemical species or reactive species.

A discharge mechanism (not shown) is provided at the tip end of the nozzle 12. To this discharge mechanism, various types of discharge mechanisms are applicable. Examples of such applicable discharge mechanisms include mechanisms with common mechanical shutters and mechanisms of a charge control type, a pressure vibration type, an electromechanical type (i.e., a so-called piezoelectric type), an electrothermal type, an electrostatic attraction type, etc.

The material reservoir 11 is used to store and hold a precursor material of the chemical species that is used as the material for film formation or patterning and, for example, stores a material for forming a luminescent layer, electron transport layer, positive hole transport layer, or the like of a semiconductor element such as a transistor, a light-emitting diode, an organic electroluminescent element, or the like such that the material is held by a holder (not shown) such as a cell, a crucible, or the like.

The heating section 13 provided between the material reservoir 11 and the plurality of nozzles 12 functions as the chemical species generation section for generating the chemical species with the material held within the material reservoir 11 as the precursor, for example. In other words, the material carried by a carrier gas from the carrier gas supply source 16 causes generation of the chemical species by the action of the heating section 13. Therefore, the temperature of the heating section 13 has only to be set in a range that allows the generation of the chemical species with the material as the precursor, and can be adjusted as necessary in accordance with the type of the material used.

Various types of heaters are applicable to the heating section 13 as long as they are capable of generating the chemical species from the precursor material. Examples of such applicable heaters include a radiant tube heater, a sheath (pipe) heater, a plug heater, a flange heater, a finned heater, a cartridge heater, a microheater, a cast heater, a hand heater, a plate heater, a block heater, a quartz heater, a silicon rubber heater, a ribbon heater, a carbon heater, an Ni—Cr heating element, an Fe—Cr heating element, an SiC heating element, etc. The sheath (pipe) heater is formed by placing a heating wire (an Nichrome wire, an iron-chromium wire, or the like) in a metal pipe (i.e., a sheath) using magnesia for an insulating material and increasing a filling density by a drawing process in order to allow heat from the heating wire to easily transmit to a surface of the metal pipe.

Heaters with an electromagnetic wave generator that generates a high frequency wave, a microwave, or the like are also applicable to the heating section 13. In addition, a gas may be introduced into the heating section 13 as necessary, e.g., a reactive gas such as oxygen, chlorine, fluorine, or the like, or an inert gas such as argon, helium, nitrogen, or the like. A method of heating employed in the heating section 13 is selected appropriately considering physical factors such as the boiling point and melting point of the material used, etc., chemical factors such as a reaction mode, etc., the type and amount of the chemical species to be generated, and the like.

In addition, a catalyst or the like may be provided inside the heating section 13 in order to accelerate the generation of the chemical species or adjust generation efficiency, a reaction temperature, or the like.

The relationship between the heating section 13, which functions as the chemical species generation section, and the plurality of nozzles 12 is as follows. The plurality of nozzles 12 are provided on a discharge head (not shown). The discharge head is connected to the heating section 13 and is so constructed that the chemical species generated in the heating section 13 and supplied from the heating section 13 is separated into a plurality of channels within the discharge head and transmitted to each of the nozzles 12. Alternatively, the discharge head may be connected to the heating section 13 and be so constructed that the chemical species generated in the heating section 13 and supplied from the heating section 13 is separated into a plurality of channels before reaching the discharge head and thus transmitted to each of the nozzles 12 without the channel separation within the discharge head. In this case, it is possible to eliminate unevenness in energy loss because of the channel separation within the nozzles and allow the supply of the chemical species to be performed more evenly.

A mechanism for emitting the chemical species heats the material supplied into the heating section 13, and thereby generates the chemical species from the material and emits the chemical species from the heating section 13. This discharge mechanism includes a means of heating for heating the material inside the heating section 13, which functions as the chemical species generation section, and is configured to control the timing of heating in order to control the timing of the discharge of the chemical species. Examples of the means of heating for emitting the chemical species include those using an electric heater, lasers such as an nitrogen laser, a YAG laser, etc., a high-frequency heater, etc. Note that the means of heating is not limited to these examples, but various known heaters are applicable thereto. In the case where the heating section 13 heats the material to generate and emit the chemical species, it is preferable that the means of heating be provided so as to heat the material or the chemical species located close to a surface of the heating section 13 that faces the substrate 15. Thus, it becomes possible to allow the chemical species to form a film effectively.

The carrier gas supply source 16 carries the material from the material reservoir 11 to the plurality of nozzles 12 using generally an inert gas, such as helium, argon, nitrogen, or the like, as the carrier gas. Depending on the type of the material, a reactive gas, such as oxygen (O₂), chorine, fluorine or the like, that reacts with the material may be used as the carrier gas to carry the material to the material reservoir 11. The carrier gas carried to the material reservoir 11 accompanies and carries the precursor material from the material reservoir 11 to the heating section 13, and further accompanies and carries the chemical species generated from the material within the heating section 13 to the plurality of nozzles 12. Depending on the type of the discharge mechanism of the nozzles 12, the material may be emitted into the chamber 14 without using the carrier gas from the carrier gas supply source 16.

The pressure within the chamber 14 can be set properly in accordance with various conditions, such as patterning precision, deposition rate, types of the material and its precursor, etc., but in the present embodiment, the chamber 14 is provided with a vacuum atmosphere. Making the inside of the chamber 14 a high vacuum allows the gaseous material discharged from the nozzles 12 to be in the free jet or ultrasonic molecular jet or in a state resembling it as described above, producing an advantage in forming a fine pattern or film.

In the case where the chamber 14 is provided with a vacuum atmosphere, the chamber 14 may be connected via the pipe 19 to the vacuum device P, such as a pump or the like, to provide the vacuum atmosphere, and may have the door (not shown) attached thereto in an airtight manner. The door is used to put the substrate 15 to be subjected to patterning in and out of the chamber 14. The vacuum device P is configured to become capable of adjusting the inside of the chamber 14 at a high degree of vacuum by the combination of a turbo-molecular pump, a rotary pump, etc. In this case, one end of the pipe 19 that connects the vacuum device P and the chamber 14 is open within the chamber 14, and thus an operation of the vacuum device P, which will be described below, is able to evacuate the chamber 14 to provide a high vacuum atmosphere.

When providing the vacuum atmosphere within the chamber 14, the vacuum device P can be used to adjust the degree of vacuum within the chamber 14. The inside of the chamber 14 is adjusted at a high vacuum atmosphere of preferably 10⁻³ torr (1.33322×10⁻¹ Pa) or less, and more preferably, 10⁻⁵ torr (1.33322×10⁻³ Pa) or less. If a vacuum atmosphere of 10⁻³ torr or less is provided, it becomes possible to easily discharge materials that are otherwise not easily discharged, for example. If a vacuum atmosphere of 10⁻⁵ torr or less is provided, still more sorts of materials become capable of being discharged easily, and in addition, it becomes easy to vaporize the material discharged and turn it into a molecular beam. Note that in the case where the above-described vacuum device P is used, in order to prevent vibration of the pump that forms part of the device from propagating into the chamber 14, it is preferable that the pump be placed so as to be sufficiently distant from the chamber 14, or that the pump or the like additionally have a vibration isolation function.

Alternatively, the inside of the chamber 14 may be provided with an inert gas atmosphere. In this case, an atmosphere of helium, argon, nitrogen, or the like, i.e., the same inert gas used as the carrier gas, is preferable.

The substrate stage 17 is arranged directly below the nozzle orifice 12a and holds and secures the substrate 15 used for manufacturing an electro-optic device, for example. The substrate stage 17 is provided with a movement mechanism 18 that enables the substrate 15 held and secured to move in X, Y, and Z directions relative to the nozzle orifice 12a. Specifically, the movement mechanism 18 is provided with a Z movement portion (not shown) that is capable of moving and positioning the substrate 15 in a vertical direction (i.e., the Z direction) relative to the nozzle orifice 12a to adjust the distance between the substrate 15 and the nozzle orifice 12a, and an X movement portion (not shown) and a Y movement portion (not shown) that are capable of moving and positioning the substrate stage 17 in horizontal directions (i.e., the X direction and the Y direction, respectively) relative to the nozzle orifice 12a. The movement mechanism 18 is configured to be capable of controlling an operation of each of these moving portions in accordance with a setting of a control section (not shown). The X movement portion, the Y movement portion, and the Z movement portion are formed by linear motors, for example.

In addition, a means of temperature adjustment (not shown) of a water-cooled type or the like is provided on a mounting surface of the substrate stage 17. This adjusts the temperature of the substrate 15 on the substrate stage 17 so that the substrate 15 has a desired temperature.

Since the film forming apparatus according to the present embodiment has the above-described mechanism for changing the relative position between the nozzle 12 and the substrate stage 17 or the substrate 15, it is possible to control the distance between the substrate 15 (or the substrate stage 17) and the nozzle 12 and provide a mechanism for scanning. This makes it possible to set a plurality of relative positions between the nozzles 12 and the substrate stage 17, and allow the nozzles 12 in their respective positions set to discharge the chemical species to form a plurality of films.

### Second Embodiment

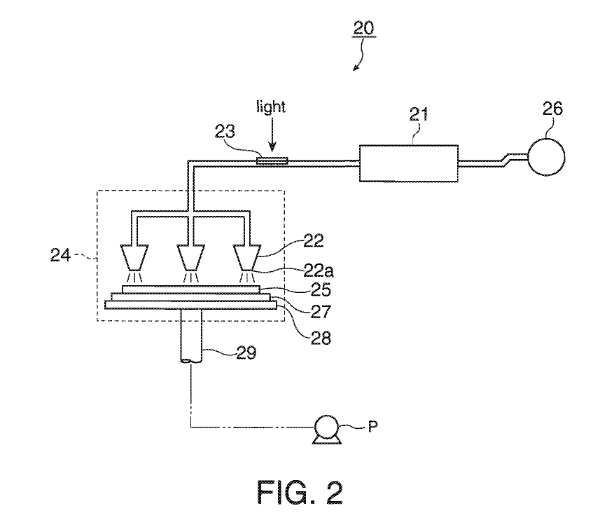

FIG. 2 is a schematic diagram illustrating a structure of a second embodiment of the film forming apparatus according to the invention.

In FIG. 2, a film forming apparatus 20 according to the second embodiment includes a material reservoir 21 for retaining a predetermined material and a plurality of nozzles 22, provided downstream of the material reservoir 21 via a flow channel, for carrying out a discharge to form a film. In addition, between the material reservoir 21 and the plurality of nozzles 22 is provided an optical window 23 that functions as a chemical species generation section for generating a chemical species, such as a reactive species or the like, with the aforementioned material as a precursor. Note that in this film forming apparatus 20, a light that is capable of generating the chemical species at the chemical species generation section may be introduced using an optical fiber or the like without using the optical window 23.

The film forming apparatus 20 according to the second embodiment has the same structure as that of the above-described film forming apparatus 10 according to the first embodiment except that the heating section 13 in the first embodiment is replaced by the optical window 23.

The film forming apparatus 20 further includes a chamber 24 that is configured to have arranged therein the plurality of nozzles 22, a substrate 25, on which a film is to be formed of the chemical species discharged from the nozzles 22, and a substrate stage 27 on which the substrate 25 is placed. The chamber 24 is connected to a vacuum device P via a pipe 29, and has a door (not shown) attached thereto in an airtight manner. The door is used to place the substrate stage 27 in an internal space of the chamber 24 and put the substrate 25 to be subjected to patterning in and out of the chamber 24.

Each nozzle 22 has a tip end at which a nozzle orifice 22a is formed, and the tip end is arranged inside the chamber 24. On the outside of the chamber 24, a rear end of the nozzle 22 is connected via the optical window 23 to the material reservoir 21, which functions as a supply source of the material. In addition, a carrier gas supply source 26 is connected to the material reservoir 21. The nozzle 22 is capable of discharging a gaseous material. In the case where the difference in pressure between the nozzle 22 and the chamber 24 is sufficiently large, the gaseous material discharged from the nozzle 22 will be in a state called a free jet or supersonic molecular jet or in a state resembling such a state. In the state called a free jet or supersonic molecular jet, the energy level, in terms of electrons, vibration, rotation, etc., of the chemical species or reactive species contained in the gaseous material discharged from the nozzle 22 is the lowest level, i.e., a so-called cooled state. Therefore, it is possible to inhibit generation of heat that may locally occur when the chemical species or reactive species reaches the substrate. This reduces influence that may be exerted on an area around a location where the film is formed, making it easy to form a tine film or pattern.

Moreover, since the chemical species or reactive species is brought into the aforementioned “cooled state”, side reaction caused by the chemical species or reactive species is inhibited. Thus, it is also possible to make uniform the structure and characteristics of the film formed of the chemical species or reactive species.

The material reservoir 21 is used to store and hold a precursor material of the chemical species that is used as the material for film formation or patterning and, for example, stores a material for forming a luminescent layer, electron transport layer, positive hole transport layer, or the like of a semiconductor element such as a transistor, a light-emitting diode, an organic electroluminescent element, or the like such that the material is held by a holder (not shown) such as a cell, a crucible, or the like.

The optical window 23 provided between the material reservoir 21 and the plurality of nozzles 22 functions as the chemical species generation section for generating the chemical species, and is constructed to be capable of applying, to the material, a predetermined light capable of generating the chemical species with the material as a precursor. That is, the material carried by the carrier gas from the carrier gas supply source 26 causes generation of the chemical species because of the light applied from the optical window 23. Therefore, the shape, size, and the like of the optical window 23 are set so that the optical window 23 is capable of generating the chemical species with the material as the precursor. The shape, size, and the like thereof can be changed as necessary in accordance with the type of the material used.

In the case where the light capable of generating the chemical species at the chemical species generation section is introduced, lasers, such as an Nd:YAG laser, an excimer laser, an nitrogen laser, a CO₂ laser, a Ti:sapphire laser, and the like can be adopted as well as common light sources, such as a mercury lamp, a zinc lamp, a xenon lamp, a halogen lamp, and the like, for example.

The carrier gas supply source 26 carries the material to the material reservoir 21 using generally an inert gas, such as helium, argon, nitrogen, or the like, as the carrier gas. Depending on the type of the material, a reactive gas, such as oxygen (O₂), chorine, fluorine or the like, that reacts with the material may be used as the carrier gas to carry the material to the material reservoir 21. The carrier gas carried to the material reservoir 21 accompanies and carries the material from the material reservoir 21 to a portion at which the optical window 23 is provided, and further accompanies and carries, to the plurality of nozzles 22, the chemical species generated from the precursor material because of the introduction of the light at the optical window 23. Depending on the type of the discharge mechanism of the nozzles 22, the material may be emitted into the chamber 24 without using the carrier gas from the carrier gas supply source 26.

In the present embodiment, the pressure within the chamber 24 can be set properly (e.g., a vacuum atmosphere, an inert gas atmosphere, or the like) in accordance with various conditions, such as patterning precision, deposition rate, types of the material and its precursor, etc., but in the present embodiment, the chamber 24 is provided with a vacuum atmosphere. Making the inside of the chamber 24 a high vacuum allows the gaseous material discharged from the nozzles 22 to be in the free jet or ultrasonic molecular jet or in a state resembling it as described above, producing an advantage in forming a fine pattern or film. The details of the case where the chamber 24 is provided with a vacuum atmosphere and of the case where the chamber 24 is provided with an inert gas atmosphere are similar to those in the above-described first embodiment.

The relationship between the optical window 23, which functions as the chemical species generation section, and the plurality of nozzles 22 is similar to the relationship between the heating section 13 and the plurality of nozzles 12 in the first embodiment. The mechanism for emitting the chemical species is similar to that in the first embodiment.

### Third Embodiment

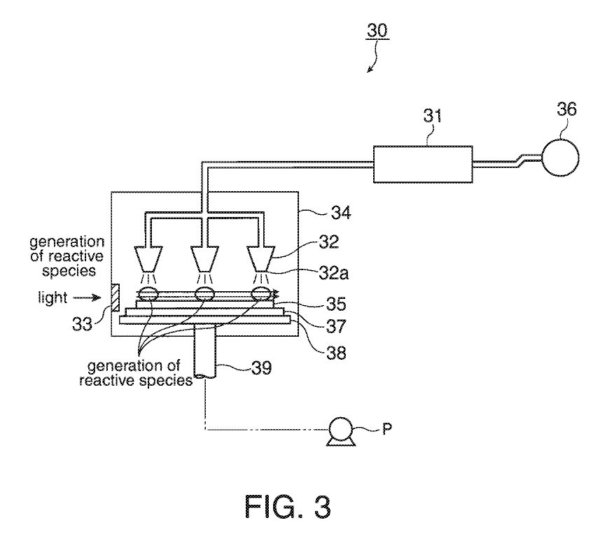

FIG. 3 is a schematic diagram illustrating a structure of a third embodiment of the film forming apparatus according to the invention.

In FIG. 3, a film forming apparatus 30 according to the third embodiment includes a material reservoir 31 for retaining a predetermined material, a plurality of nozzles 32, provided downstream of the material reservoir 31 via a flow channel, for discharging the material, and a substrate 35 on which a film is to be formed by discharging of the plurality of nozzles 32. The film forming apparatus 30 further includes an optical window 33 that functions as a means of chemical species generation for generating a chemical species, such as a reactive species or the like, with the material as a precursor when the plurality of nozzles 32 have discharged the material onto the substrate 35. Note that in this film forming apparatus 30, a light that is capable of generating the chemical species may be introduced using an optical fiber or the like as the means of chemical species generation without using the optical window 33.

The film forming apparatus 30 according to the third embodiment has the same structure as that of the film forming apparatus 20 according to the second embodiment except that the location of the optical window, which functions as the chemical species generation means (section), is changed to a location downstream (from the viewpoint of the flow of the material) of the plurality of nozzles 32, i.e., a location between the plurality of nozzles 32 and the substrate 35. Note that, to points that will not be particularly specified with respect to the present embodiment, matters as described with respect to the above-described embodiments are applied as necessary.

The film forming apparatus 30 further includes a chamber 34 that is configured to have arranged therein the plurality of nozzles 32, the substrate 35, on which a film is to be formed of the chemical species generating from the material discharged from the nozzles 32, and a substrate stage 37 on which the substrate 35 is placed. In addition, as illustrated in FIG. 3, the chamber 34 is provided, at a predetermined location, with the optical window 33 for introducing a light that travels in a horizontal direction between the plurality of nozzles 32 and the substrate 35 to generate the chemical species. The other portions of the chamber 34 than the optical window 33 are configured to block the light. The chamber 34 is connected to a vacuum device P via a pipe 39, and has a door (not shown) attached thereto in an airtight manner. The door is used to place the substrate stage 37 in an internal space of the chamber 34 and put the substrate 35 that is to be subjected to patterning in and out of the chamber 34.

Each nozzle 32 has a tip end at which a nozzle orifice 32a is formed, and the tip end is arranged inside the chamber 34. On the outside of the chamber 34, a rear end of the nozzle 32 is connected to the material reservoir 31, which functions as a supply source of the material. In addition, a carrier gas supply source 36 is connected to the material reservoir 31. The nozzle 32 is capable of discharging a gaseous material. In the case where the difference in pressure between the nozzle 32 and the chamber 34 is sufficiently large, the gaseous material discharged from the nozzle 32 will be in a state called a free jet or supersonic molecular jet or in a state resembling such a state. In the state called a free jet or supersonic molecular jet, the energy level, in terms of electrons, vibration, rotation, etc., of the chemical species or reactive species contained in the gaseous material discharged from the nozzle 32 is the lowest level, i.e., a so-called cooled state. Therefore, it is possible to inhibit generation of heat that may locally occur when the chemical species or reactive species reaches the substrate. This reduces influence that may be exerted on an area around a location where the film is formed, making it easy to form a fine film or pattern.

Moreover, since the chemical species or reactive species is brought into the aforementioned “cooled state”, side reaction caused by the chemical species or reactive species is inhibited. Thus, it is also possible to make uniform the structure and characteristics of the film formed of the chemical species or reactive species.

The material reservoir 31 is used to store and hold a precursor material of the chemical species that is used as the material for film formation or patterning and, for example, stores a material for forming a luminescent layer, electron transport layer, positive hole transport layer, or the like of a semiconductor element such as a transistor, a light-emitting diode, an organic electroluminescent element, or the like such that the material is held by a holder (not shown) such as a cell, a crucible, or the like.

The optical window 33 functions as the means of chemical species generation for generating the chemical species, and is configured to be capable of applying, to the material, a predetermined light that is capable of generating the chemical species with the material as the precursor. That is, the material carried by the carrier gas from the carrier gas supply source 36 causes, when the material has been discharged from the plurality of nozzles 32, the generation of the chemical species by the action of the light applied from the optical window 33 before being adhered to the substrate 35. Therefore, the shape, size, and the like of the optical window 33 are set so that the optical window 33 is capable of generating the chemical species with the material as the precursor. The shape, size, and the like thereof can be changed as necessary in accordance with the type of the material used.

In the case where the light capable of generating the chemical species is introduced as the means of chemical species generation, lasers, such as an Nd:YAG laser, an excimer laser, an nitrogen laser, a CO₂ laser, a Ti:sapphire laser, and the like can be adopted as well as common light sources, such as a mercury lamp, a zinc lamp, a xenon lamp, a halogen lamp, and the like, for example.

The carrier gas supply source 36 carries the material to the material reservoir 31 using generally an inert gas, such as helium, argon, nitrogen, or the like, as the carrier gas. Depending on the type of the material, a reactive gas, such as oxygen (O₂), chorine, fluorine or the like, that reacts with the material may be used as the carrier gas to transfer the material to the material reservoir 31. The carrier gas transferred to the material reservoir 31 accompanies and carries the precursor material from the material reservoir 31 to the plurality of nozzles 32. Depending on the type of the discharge mechanism of the nozzles 32, the material may be emitted into the chamber 34 without using the carrier gas from the carrier gas supply source 36.

In the present embodiment, the pressure within the chamber 34 can be set properly (e.g., a vacuum atmosphere, an inert gas atmosphere, or the like) in accordance with various conditions, such as patterning precision, deposition rate, types of the material and its precursor, etc., but in the present embodiment, the chamber 34 is provided with a vacuum atmosphere. Making the inside of the chamber 34 a high vacuum allows the gaseous material discharged from the nozzles 32 to be in the free jet or ultrasonic molecular jet or in a state resembling it as described above, producing an advantage in forming a fine pattern or film. The details of the case where the chamber 34 is provided with a vacuum atmosphere and of the case where the chamber 34 is provided with an inert gas atmosphere are similar to those in the above-described first embodiment.

In the third embodiment, a means of heating as used in the first embodiment may be provided in place of or in addition to the means of introducing the light or the means of providing the optical window as the means of chemical species generation.

In order to achieve a fine pattern using the film forming apparatus, it is necessary to position the nozzles and the substrate so as to be close to each other. Therefore, in the case where the light is introduced so as to travel between the nozzles 32 and the substrate 35 as in the third embodiment, it is preferable that precise optical alignment be performed.

The relationship between the optical window 33, which can be used to generate chemical species, and the plurality of nozzles 32 is similar to the relationship between the heating section 13 and the plurality of nozzles 12 in the first embodiment. The mechanism for emitting the chemical species is similar to that in the first embodiment.

In the film forming apparatus according to an aspect of the invention, electromagnetic waves other than common light may be used to generate the chemical species or turn the chemical species into a gaseous state. For example, a microwave, a radiofrequency wave, or the like may be used to generate the chemical species in a plasma state or the like.

According to an aspect of the invention, it is possible to discharge the chemical species generated at the chemical species generation section from one or more nozzles in a gaseous state, for example. In particular, it is preferable that the chemical species generated by heat, light, or the like be turned into a free jet and that patterning be performed by direct drawing. In this case, a large number of processes can be omitted. In addition, according to the preferred embodiments of the invention, the nozzles do not have to be equipped with a piezoelectric element, and therefore a smaller nozzle pitch may be accomplished. This enables finer direct drawing as compared with the case of an inkjet process or the like. Further, in contrast to common mask patterning, if patterning is performed while moving the nozzles that discharge the material as in the preferred embodiments of the invention, it is possible to maintain evenness in distance between the nozzles and the substrate on which the material is arranged. Thus, unevenness in the thickness of films or the like can be reduced. Still further, since a problem of deflection of a mask does not occur, the invention is used for a large-sized substrate.

Note that, when patterning is performed while moving the nozzles that discharge the material as in the preferred embodiments of the invention, the patterning may be performed using a mask. In this case, as compared with the case where no mask is used, there is an advantage in that a film having a desired shape can be formed by using a mask having a desired pattern, such as a square, a circle, or the like.

In the film forming apparatus according to the invention, a chemical species is generated by heat, light, or an electromagnetic wave, and the chemical species is discharged from a plurality of nozzles, whereby a collective forming of a plurality of films is achieved. The term “collective forming of a plurality of films” used herein refers to the case where a plurality of discharging operations are performed at the same time and to the case where the plurality of nozzles discharge the chemical species with an interval of time between each nozzle.

With the film forming apparatus according to the invention, it is possible to carry out fine patterning suitable for manufacturing a wiring circuit or the like.

The film forming apparatus according to the invention is applicable to forming various types of films, such as an insulator, a semiconductor, a good conductor, a superconductor, and the like.

Further, the film forming apparatus according to the invention is also effective for a combinatorial process. That is, it is possible to form, in a plurality of areas on a substrate, a plurality of films formed with different conditions for film formation. For example, it is possible to accomplish the formation of a plurality of films by adjusting conditions, such as the pressure for the carrier gas or the reactive gas, the degree of decompression for the chamber, or the like. Thus, it is possible to change the conditions for film formation by one operation of adjusting the conditions.

Examples of materials that can be used as the precursor of the chemical species used in the film forming apparatus according to the invention include: compounds with an organic group, such as dialkylzinc (ZnR₂), trimethyl gallium (Me₃Ga), tetramethylsilane (Me₄Si), trimethylarsine (Me₃As), tetrakis (dimethylamide) zirconium, etc.; compounds containing metal, such as tantalum pentachloride, tungsten hexacarbonyl (W(CO)₆), etc.; compounds with substituents other than the organic group or a ligand, such as phosphine, etc.; and simple substances, such as red phosphorus, yellow phosphorus, etc. At room temperature and atmospheric pressure (25° C., 1 atm), liquid silicon compounds (e.g., silicon compounds 1 to 4 as illustrated in FIG. 5) or the like can be cited. In particular, the silicon compounds 1 to 4 are preferable as they involve a relatively low risk of ignition, explosion, and the like, and are thus easy to handle. In the case where the silicon compound 3 or 4 is used, it is preferable that a chemical species, such as a reactive species, be generated by a light with a wavelength of approximately 200 nm. The dialkylzinc (ZnR₂), which can be used as the precursor of ZnO, is preferable in that it is easy to evaporate and easy to be decomposed to a desired degree.

For the precursor material, materials that cause the generation of the chemical species by having at least one chemical bond thereof broken or by transfer reaction are preferable. For the material, precursors that are capable of generating a reactive species, such as a radical, an ion radical, an ion, a low-valent chemical species (e.g., carbene, silylene, etc.), or the like as the chemical species are preferable. Also preferable for the material are precursors that are capable of generating a chemical species capable of polymerization.

For example, it is possible to form a silicon film by carrying silylene generated by heating a precursor of silylene that is a divalent silicon species to the plurality of nozzles and discharging it. Silicon compounds heretofore used in a liquid-phase or vapor-phase process generally contain a large amount of hydrogen, and therefore they involve a risk of ignition, explosion, and the like. In the case where the compound 1 or 3 as illustrated in FIG. 5 is used as the precursor of silylene in particular, there is an advantage in ease of handling as compared with the case of such risky silicon compounds.

Examples of the reactive species as the chemical species generated from the precursor material at the chemical species generation section include: unstable chemical species, such as a radical, an ion, a radical ion, silaethene. silylin, disilene, digermene, etc., low-valent chemical species, such as carbene, silylene, etc., and the like. The term “unstable chemical species” used herein refers to a chemical species that is thermodynamically or kinetically unstable, for example. That is, the term also refers to a chemical species that will easily exceed an activation potential to be converted into a different compound. The term also refers to a chemical species that will easily react with another reactive agent, and the like.

With a chemical species that is capable of polymerization in particular, which is capable of polymerizing on the substrate, it is easy to form a film of macromolecules or form a macrostructure on the substrate. Examples of the chemical species that are capable of polymerization include unstable chemical species, such as silaethene, silylin, disilene, digermene, etc., low-valent chemical species, such as carbene, silylyne, etc., and the like.

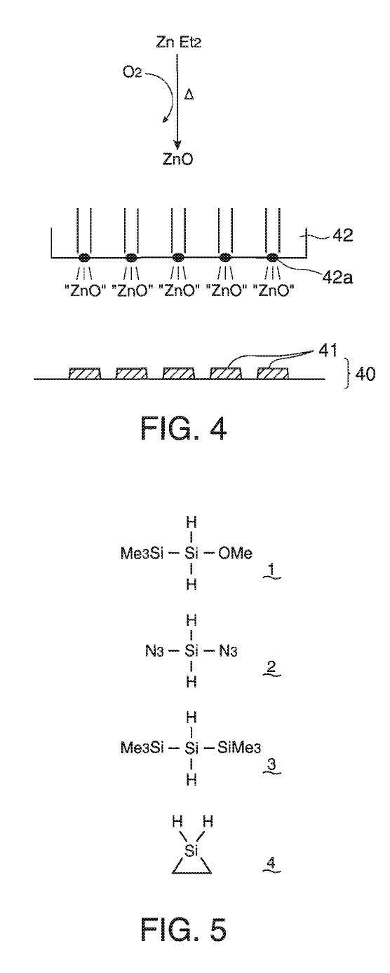

FIG. 4 is a schematic diagram illustrating the case where the film forming apparatus 10 according to the first embodiment is implemented with diethyl zinc (ZnEt₂) for the material and oxygen (O₂) for the carrier gas. ZnEt₂, which has been contained and held in the material reservoir 11, is accompanied and carried by the carrier gas supplied from the carrier gas supply source 16 to the heating section 13. Then, heating at the heating section 13 causes ZnEt₂ to react with O₂, resulting in ZnO as the chemical species. Thereafter, ZnO is discharged from the nozzle orifice 42a of the nozzle 42, and thus, a luminescent layer 41 in an LED array 40 can be formed in an array, for example.

In the film forming apparatus according to the invention, it is preferable that the apparatus include a mechanism for changing the relative position between the nozzle and the substrate stage or the substrate. Also, in the film forming apparatus according to the invention, a plurality of relative positions may be set between the nozzles and the substrate stage. Also, it is preferable that the nozzles in their respective positions set be capable of discharging the material or the chemical species independently of one another.

The film forming apparatus according to the invention is so constructed as to be capable of forming a plurality of films on the substrate. Thus, it is possible to form a plurality of films on the substrate. Exemplary modes of films formed by the film forming apparatus according to the invention include an island structure, films formed in a plurality of predetermined regions on the substrate, and the like.

Next, a process of film formation and patterning using the film forming apparatus having the above-described structures will now be described with reference to an exemplary case where direct patterning of silicon is carried out to manufacture a TFT.

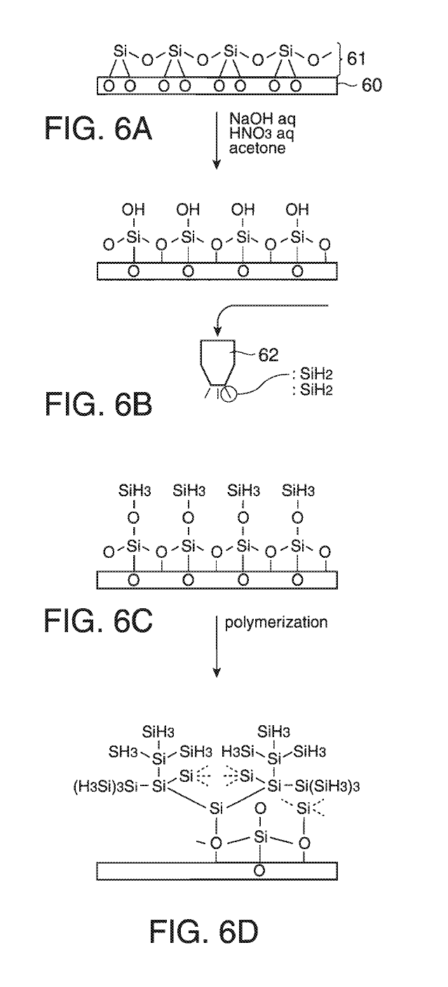

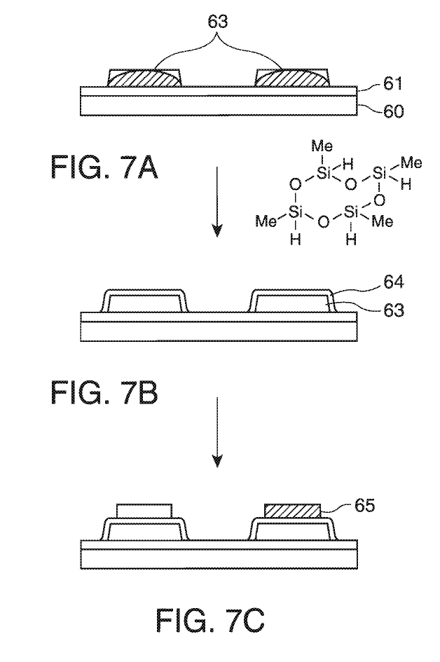

FIGS. 6A to 6D are schematic process diagrams illustrating processes in direct patterning of silicon for inserting silylene using the film forming apparatus according to the invention. FIGS. 7A to 7C are schematic process diagrams illustrating processes for manufacturing the TFT after films are formed using the film forming apparatus according to the invention.

A glass substrate 60 on which a foundation layer 61 formed of Si—O has been previously provided is prepared (see FIG. 6A). Treatments of the foundation layer 61 with aqueous sodium hydroxide, aqueous nitric acid, and acetone provide hydroxyl groups on a surface of the foundation layer 61 (see FIG. 6B).

Next, insertion of silylene is performed on the surface of the foundation layer 61 on the substrate in a state as illustrated in FIG. 6B (see FIG. 6C). At this time, using the film forming apparatus according to the invention, one of the aforementioned silicon compounds 1 to 4 is held in the material reservoir as the material, and the material is accompanied and carried downstream (i.e., in the direction of nozzles) by the carrier gas via the flow channel, for example. Next, at the chemical species generation section provided upstream of a plurality of nozzles 62, silylene (:SiH₂), which is the chemical species, is generating from the material by the action of heat, light, or the like. This silylene is discharged from the plurality of nozzles 62 to form a film on the foundation layer 61, which has the hydroxyl groups on the surface thereof. Then, the silylene acts with the hydroxyl groups to cause an insertion reaction of silylene, whereby a combination of SiH₃—O is formed on the surface thereof (see FIG. 6C).

In the case where the insertion reaction of silylene is caused as described above, it is preferable that a foundation layer for film formation that contains a compound that has a bond with which silylene is capable of insertion reaction be used. Examples of bonds with which silylene is capable of insertion reaction include a Z-H group (where Z refers to chalcogen), such as the O—H group as illustrated in the above example, etc., a Y—H group (where Y refers to elements in the 14th family), and the like.

After SiH₃—O is formed on the surface, silylene is further polymerized to form a surface as illustrated in FIG. 6D. Thereafter, heat annealing or the like may be carried out for crystallization as necessary.

As a result of the above-described film formation, a plurality of silicon semiconductor films 63 are formed on the foundation layer 61 provided on the glass substrate 60 (see FIG. 7A). Next, SiO₂ is deposited on the silicon semiconductor films 63 by CVD using a predetermined silicon compound to form gate insulating films 64 (see FIG. 7B). Further, on each of the gate insulating films 64, a gate electrode 65 is formed (see FIG. 7C). After that, common known processes for manufacturing a transistor are performed to obtain the TFT.

For formation of the gate electrode 65, AlMe₃, which is relatively easy to be decomposed by heat, may be used as a CVD material. Note that in the processes for manufacturing the TFT, Al generated by irradiating aluminum metal with laser beams may be deposited, as described in JP-A-2003-197531. In the formation of the films, it is possible to set the size of the films by setting the distance between the nozzles and the substrate properly.

The invention has been described in detail above with reference to the preferred embodiments. However, needless to say, the invention is not limited to those embodiments in any respect.

For example, the substrate may be a glass substrate as described in the above-described embodiments, or alternatively may be an active matrix substrate, or the like.

In the invention, as the means for generating the chemical species at the chemical species generation section, a millimeter wave, a submillimeter wave, a microwave, an infrared ray, a visible ray, an ultraviolet ray, a vacuum ultraviolet ray, or an X-ray can be used as the electromagnetic wave to generate the chemical species.

The film forming apparatus according to the invention is useful for omitting a large number of processes that have been required heretofore, and is capable of fine direct patterning.

What is claimed is:

1. A film forming apparatus, comprising:
a material reservoir that retains a material;
at least one nozzle that discharges the material or a chemical species generated from the material as a precursor; and
a chemical species generation section that generates the chemical species.

2. The film forming apparatus according to claim 1,
the at least one nozzle being a plurality of nozzles.

3. The film forming apparatus according to claim 1,
the chemical species generation section being provided with a heating section.

4. The film forming apparatus according to claim 1,
the chemical species generation section being configured to introduce a light or provided with an optical window.

5. The film forming apparatus according to claim 1,
the chemical species generation section being configured to be capable of emitting an electromagnetic wave.

6. The film forming apparatus according to claim 1, further comprising a stage on which a substrate on which a film formed of the chemical species is to be arranged is placed.

7. The film forming apparatus according to claim 1, further comprising a mechanism that changes a relative position between the at least one nozzle and the stage or the substrate.

8. The film forming apparatus according to claim 1, the at least one nozzle being capable of carrying out discharge in their respective positions that result from setting a plurality of relative positions between the at least one nozzle and the stage.

9. The film forming apparatus according to claim 8,
the apparatus being configured to be capable of forming a plurality of films on the substrate.

10. The film forming apparatus according to claim 1,
the chemical species generation section generating a reactive species as the chemical species.

11. The film forming apparatus according to claim 1,
the chemical species generation section generating a species capable of polymerization as the chemical species.

12. The film forming apparatus according to claim 1,
the material being a compound containing metal.

13. The film forming apparatus according to claim 1, further comprising a chamber that has arranged therein the at least one nozzle and a substrate on which a film formed of the chemical species is to be arranged, and
a pressure within the chamber being adjustable so as to be 1.33322×10⁻¹ Pa or less.

14. The film forming apparatus according to claim 1,
the at least one nozzle generating a free jet as a gaseous material.
